(19) United States
(12) Patent Application Publication
(10) Pub. No.: US 2012/0274322 A1
(43) Pub. Date: Nov. 1, 2012

(54) MAGNETIC RESONANCE IMAGING APPARATUS

(76) Inventors: Sangwoo Lee, Seoul (KR); Gaohong Wu, Waukesha, WI (US)

(21) Appl. No.: 13/095,424

(22) Filed: Apr. 27, 2011

(51) Int. Cl. G01R 33/44

(52) U.S. Cl. 324/309

(57) ABSTRACT

A magnetic resonance imaging apparatus that carries out a pulse sequence for making a signal of a first substance within an object smaller than a signal of a second substance within the object. The pulse sequence includes an α°-pulse for exciting the object, a refocus pulse for refocusing a phase of spin within a region excited by the α°-pulse, and a readout gradient field for acquiring a magnetic resonance signal from the region. The α°-pulse has a spectral selectivity such that a transverse magnetization of the first substance is made smaller than a transverse magnetization of the second substance. The refocus pulse has a spectral selectivity such that a phase of spin of the second substance is refocused and refocusing of a phase of spin of the first substance is suppressed.

### BACKGROUND OF THE INVENTION

The present invention relates to a magnetic resonance imaging apparatus capable of carrying out a pulse sequence including α°-pulse and refocus pulse.

There are known methods of using SPSP pulses (Spectral Spatial Pulses) as a fat suppression method. One such method is described in “Slice-Selective Fat Saturation in MR Angiography Using Spatial-Spectral Selective Prepulses,” by J. Forster, et al., Journal of Magnetic Resonance Imaging, Vol. 8, No. 3, pp. 583-589 (1998) (hereinafter referred to as “Forster”).

SPSP pulses include multiple subpulses and are widely used in imaging using functional magnetic resonance imaging (fMRI), diffusion-weighted imaging, or the like. However, conventional SPSP pulses have their subpulses limited in maximum pulse width to a certain extent; therefore, they involve problems of degradation in a spatial excitation profile and increased minimum slice thickness. The maximum pulse width of a subpulse can be determined by, for example, the following expression from “Design of Improved Spectral-Spatial Pulses for Routine Clinical Use” by Y. Zur, Magnetic Resonance in Medicine, Vol. 43, pp. 410-420 (2000) (hereinafter referred to as “Zur”):

1/τ≧2Δω_{wf} (Eq. 1)

where, Δω_{wf} is the chemical shift frequency of water and fat; and t is the period of a subpulse.

In the method described in Zur, the maximum period of subpulses must be made shorter than 595 μs. Therefore, slice profiles are degraded or minimum slice thicknesses are increased. For, example, in case of MRI apparatuses of 3 T (tesla), the minimum slice thickness is 3 mm or so. This makes it difficult to acquire an isotropic diffusion-weighted image under typically used FOV (24 cm) and in-plane resolution (128×128) conditions. In case of 3 T-MRI apparatus, the minimum slice thickness cannot be sufficiently reduced even with use of conventional SPSP pulses. Therefore, users of 3 T-MRI apparatuses may use a fat saturation method, as described in “H1 NMR chemical shift selective (CHESS) imaging” by A. Haase et al., Physics in Medicine and Biology, Vol. 30, No. 4, pp. 341-344 (1985) (hereinafter referred to as “Haase”), so that a slice thickness can be reduced. However, with the fat saturation method in Haase, sufficient fat suppression effect cannot be obtained as compared with methods using SPSP pulses.

Therefore, it is hoped that sufficient fat suppression effect can be obtained even when the slice thickness is thin.

Further, in some cases, instead of fat suppression, water suppression is required. In the other cases, suppression of a substance (e.g. metabolite) different from fat and water is required. Therefore, it is also hoped that a substance different from fat can be suppressed.

### BRIEF DESCRIPTION OF THE INVENTION

An aspect of the invention is a magnetic resonance imaging apparatus that carries out a pulse sequence for making a signal of a first substance within an object smaller than a signal of a second substance within the object.

The pulse sequence has an α°-pulse for exciting the object, a refocus pulse for refocusing the phase of spin in a region excited by the α°-pulse, and a readout gradient field for acquiring magnetic resonance signal from the region.

The α°-pulse has such spectral selectivity that the transverse magnetization of the first substance is made smaller than the transverse magnetization of the second substance.

The refocus pulse has such spectral selectivity that the phase of the spin of the second substance is refocused and the refocusing of the phase of the spin of the first substance is suppressed.

In the embodiments described herein, the refocus pulse is transmitted before the readout gradient field. The refocus pulse has such spectral selectivity that the phase of the spin of the second substance is refocused and the refocusing of the phase of the spin of the first substance is suppressed. Therefore, even when the thickness of the region excited by the α°-pulse is thin, the signal of the first substance within the object can be smaller than the signal of the second substance within the object.

### BRIEF DESCRIPTION OF THE DRAWINGS

FIG. 1 is a schematic diagram of an exemplary magnetic resonance imaging apparatus.

FIG. 2 is a diagram for explaining a pulse sequence used in the magnetic resonance imaging apparatus shown in FIG. 1.

FIG. 3 shows a real inverted region.

FIGS. 4A and 4B show the results of Bloch simulation on the 90o-pulse Pα and the refocus pulse Pᵣ₁.

FIG. 5 shows the slice profile at the position (line L1-L1) of off-resonance frequency 0 Hz of the simulation result A.

FIG. 6 shows the spectral selectivity in the center at the slice position of the simulation results A and B.

FIG. 7 shows an example of a pulse sequence PS2 with a crusher gradient G_{c} applied to both sides of a gradient field G_{z1}.

FIG. 8 shows an example of a pulse sequence PS3 provided with multiple refocus pulses.

FIG. 9 shows an example of a pulse sequence PS4 provided with three or more refocus pulses.

FIG. 10 shows an example of a pulse sequence PS5 provided with a diffusion encode.

FIG. 11 shows an example applied to a pulse sequence in a gradient echo EPI.

### DETAILED DESCRIPTION OF THE PREFERRED EMBODIMENTS

Hereafter, description will be given to embodiments for carrying out the invention but the invention is not limited to the following embodiments.

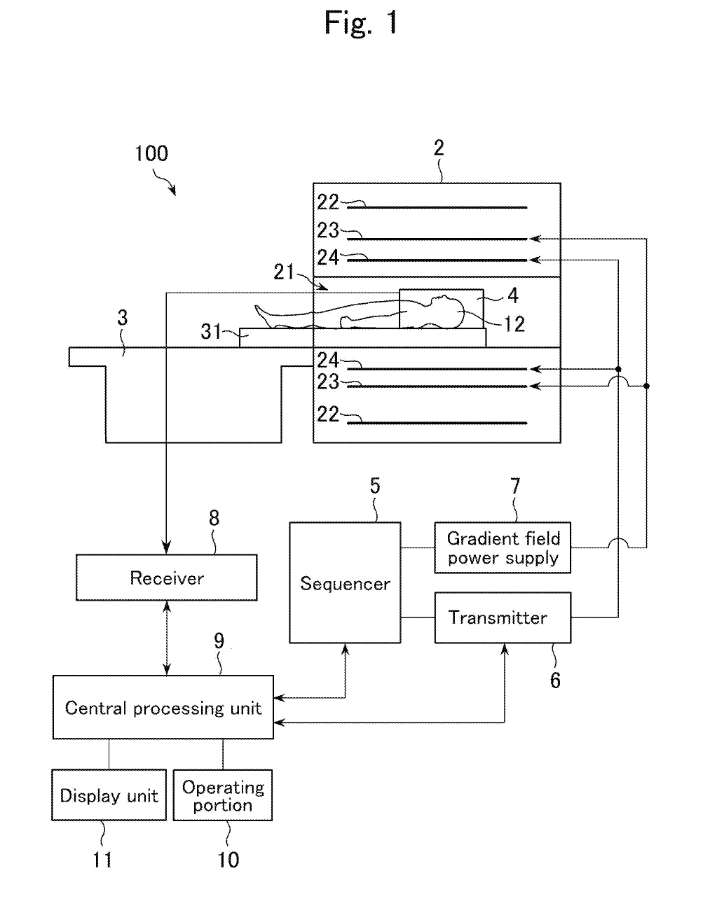

FIG. 1 is a schematic diagram of a magnetic resonance imaging apparatus 100.

The magnetic resonance imaging apparatus (hereafter, referred to as “MRI apparatus.” MRI: Magnetic Resonance Imaging) 100 includes a magnet 2, a table 3, a receiving coil 4, and the like.

The magnet 2 includes a bore 21 in which an object 12 is placed, a superconducting coil 22, a gradient coil 23, and a RF coil 24. The superconducting coil 22 applies a static magnetic field BO; the gradient coil 23 applies a gradient field; and the RF coil 24 transmits RF pulses. A permanent magnet may be used in place of the superconducting coil 22.

The table 3 has a cradle 31. The cradle 31 is so configured that it can be moved into the bore 21. The object 12 is carried into the bore 21 by the cradle 31.

The receiving coil 4 is attached to the head of the object 12. The receiving coil 4 receives magnetic resonance signals from the object 12.

The MRI apparatus 100 further includes a sequencer 5, a transmitter 6, a gradient field power supply 7, a receiver 8, a central processing unit 9, an operating portion 10, and a display unit 11.

Under the control of the central processing unit 9, the sequencer 5 sends information for obtaining an image of the object 12 to the transmitter 6 and the gradient field power supply 7.

The transmitter 6 outputs driving signals for driving the RF coil 24 based on the information sent from the sequencer 5.

The gradient field power supply 7 outputs driving signals for driving the gradient coil 23 based on the information sent from the sequencer 5.

The receiver 8 processes magnetic resonance signals received at the receiving coil 4 and outputs data obtained by this signal processing to the central processing unit 9.

The central processing unit 9 controls the operation of each part of the MRI apparatus 100 so that various operations of the MRI apparatus 100 are implemented. Examples of such operations include transferring required information to the sequencer 5 and the display unit 11, reconfiguring images based on data received from the receiver 8. The central processing unit 9 includes, for example, a computer.

The operating portion 10 is operated by an operator and inputs varied information to the central processing unit 9. The display unit 11 displays varied information.

The MRI apparatus 100 is configured as mentioned above.

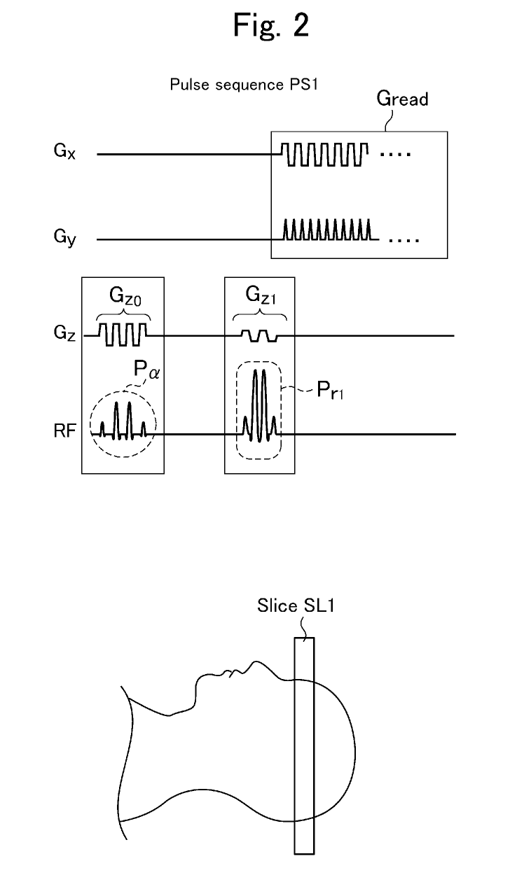

FIG. 2 is a diagram for explaining a pulse sequence used in this embodiment.

In the upper part of FIG. 2, an EPI pulse sequence PS1 is shown and in the lower part of FIG. 2, a slice SL1 excited by the pulse sequence PS1 is shown.

The pulse sequence PS1 includes an α°-pulse Pα. In the following description, it is assumed that α=90 for the sake of convenience but α° is not limited to 90°. The 90°-pulse Pα includes four subpulses. The 90°-pulse Pα is so designed that the flip angle of the spin of fat is 0° (or an angle close to 0°) but the flip angle of the spin of water is 90° (or an angle close to 90°). Therefore, the 90°-pulse Pα has such spectral selectivity that the transverse magnetization of fat is made equal to 0 (or a value close to 0) and the transverse magnetization of water is made equal to 1 (or a value close to 1).

While the 90°-pulse Pα is transmitted, a gradient field G_{z0} is applied. In this embodiment, each subpulse of the 90°-pulse Pα is not transmitted when the gradient field G_{z0} is in a negative lobe and is transmitted only when it is in a positive lobe. However, it is possible that each subpulse of the 90°-pulse Pα is not transmitted when the gradient field G_{z0} is in a positive lobe and is transmitted only when it is in a negative lobe. Further, each subpulse of the 90°-pulse Pα may be transmitted when the gradient field G_{z0} is in a negative lobe and in a positive lobe. A slice SL1 is excited by the 90°-pulse Pα and the gradient field G_{z0}.

The refocus pulse Pᵣ₁ is a 180°-pulse (inversion pulse). The refocus pulse Pᵣ₁ has such spectral selectivity that the phase of the spin of water is refocused and the refocusing of the phase of the spin of fat is suppressed. The refocus pulse Pᵣ₁ refocuses the spin of water, and thus the signal intensity of water signals can be increased. Meanwhile, the refocus pulse Pᵣ₁ suppresses the refocusing of the spin of fat, and thus the signal intensity of fat signals can be sufficiently reduced.

While the refocus pulse Pᵣ₁ is transmitted, the gradient field G_{z1} is applied. In this embodiment, each subpulse of the refocus pulse Pᵣ₁ is transmitted not only while the gradient field G_{z1} is in a positive lobe but also while it is in a negative lobe. The spin in the slice SL1 is inverted by the refocus pulse Pᵣ₁ and the gradient field G_{z1}. After that, a readout gradient field G_{read} is applied. The readout gradient field is to acquire a magnetic resonance signal from the slice SL1.

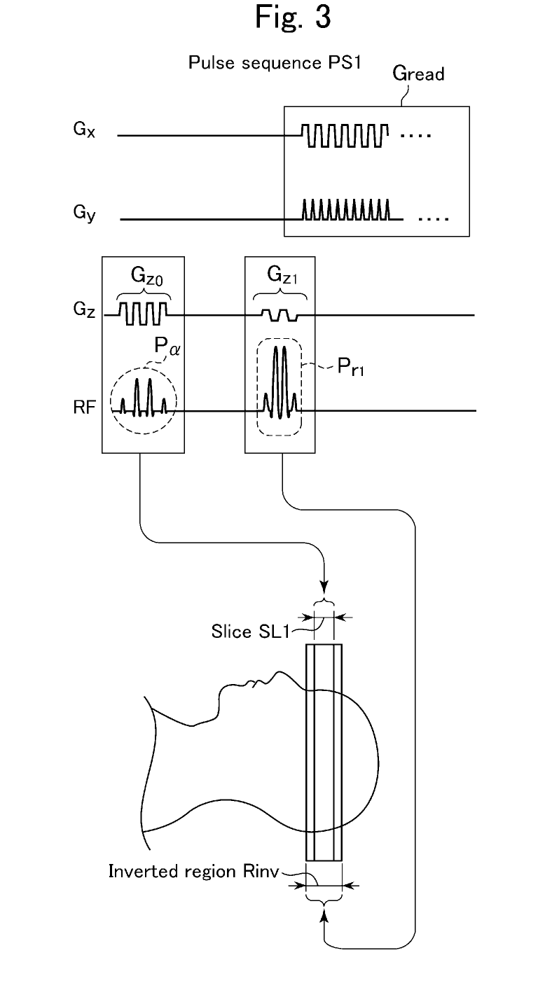

Since the refocus pulse Pᵣ₁ is a 180°-pulse (inversion pulse), ideally, the flip angle of spin should be 180° throughout the slice SL1. In reality, however, the flip angle is 180° (or an angle close to 180°) in the central part of the slice SL1; and the flip angle becomes significantly smaller than 180° as it goes close to an end of the slice SL1. Therefore, there is a possibility that the spin at an end of the slice SL1 cannot be sufficiently refocused. In reality, consequently, the region R, where the spin is inverted by a combination of the refocus pulse Pᵣ₁ and the gradient field G_{z1} is made larger than the slice SL1 as shown in FIG. 3. This makes it possible to sufficiently refocus spin throughout the slice SL1.

According to the pulse sequence PS1, an image with fat sufficiently suppressed can be obtained even though the thickness of the slice SL1 is reduced. Simulation was carried out to explain the reason for this. Hereafter, description will be given to the result of the simulation. The simulation conditions are as listed below:

(1) The simulation conditions C1 with respect to the α°-pulse Pα
Number of subpulses: 4
Spectral band width: 150 Hz
Spatial band width: 2107 Hz
Overall pulse length of α°-pulse Pα: 11.7 ms
Position of null: 150 Hz
Minimum slice thickness: 1.69 mm
   (2) The simulation conditions C2 with respect to the refocus Pulse Pᵣ₁
Number of subpulses: 4
Spectral band width: 400 Hz
Spatial band width: 2930 Hz
Overall pulse length of refocus pulse Pᵣ₁: 5.024 ms
Minimum slice thickness: 2.45 mm
   “Position of null” of the simulation conditions C1 will be described later.

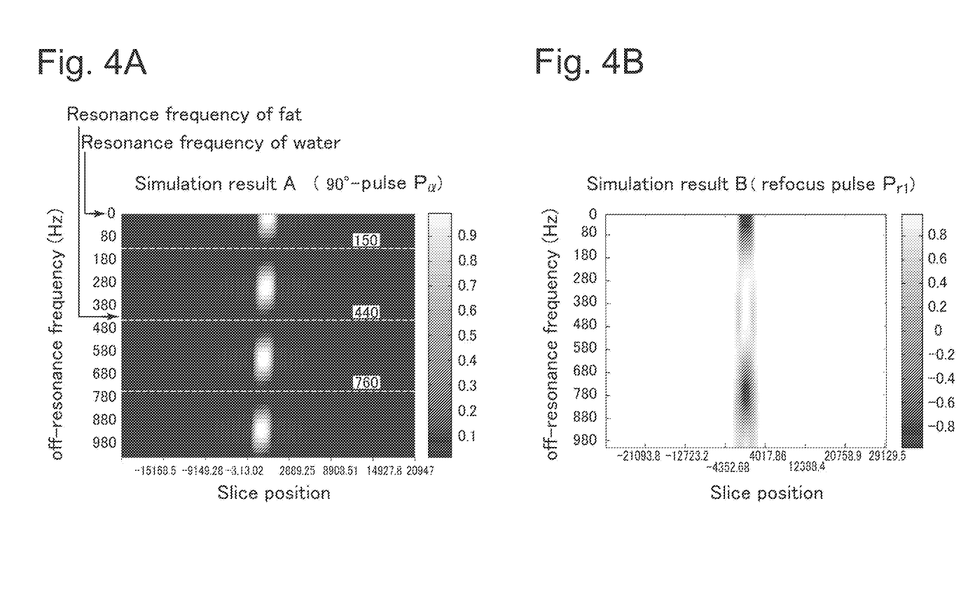

FIGS. 4 to 6 are drawings showing simulation results.

FIGS. 4A and 4B show the results of Bloch simulation on the 90°-pulse Pα and the refocus pulse Pᵣ₁.

FIG. 4A shows simulation results A and FIG. 4B shows simulation results B. The simulation result A shows the result of Bloch simulation on transverse magnetization (Mxy) at the end of the 90°-pulse Pα. The simulation result B shows the result of Bloch simulation on longitudinal magnetization (Mz) at an end of the refocus pulse Pᵣ₁. The condition of equilibrium (Mx=My=0, Mz=1) was taken as the initial condition for magnetization.

In the simulation results A and B, the horizontal axis indicates slice position and the vertical axis indicates off-resonance frequency. The value of magnetization is indicated by gray scale.

The off-resonance frequency represents a deviation from the resonance frequency of water. The resonance frequency of water is on-resonance frequency (that is, off-resonance frequency=0 Hz). In the case of 3 T MRI apparatuses, the position of off-resonance frequency 420 Hz corresponds to the position of the resonance frequency of fat.

In the simulation result A, the position of null is indicated. The “position of null” cited here indicates the position of off-resonance frequency at which transverse magnetization is most suppressed. When subpulses of the α°-pulse Pα are used only when the gradient field G_{z0} is in a positive lobe, in general, “null” is designated as “true null.” Meanwhile, when subpulses of the α°-pulse Pα are used both when the gradient field G_{z0} is in a positive lobe and when it is in a negative lobe, “null” is designated as “opposed null.” In this embodiment, subpulses of the α°-pulse Pα are used only when the gradient field G_{z0} is in a positive lobe as shown in FIG. 3; therefore, the null is equivalent to “true null.” In simulation result A, the position of null occurs at the positions of 150 Hz, 440 Hz, and 760 Hz in the ascending order. Therefore, the position (150 Hz) of the first null is made sufficiently smaller than the water fat chemical shift (420 Hz). In the above simulation conditions C1, only the position (150 Hz) of first null is indicated.

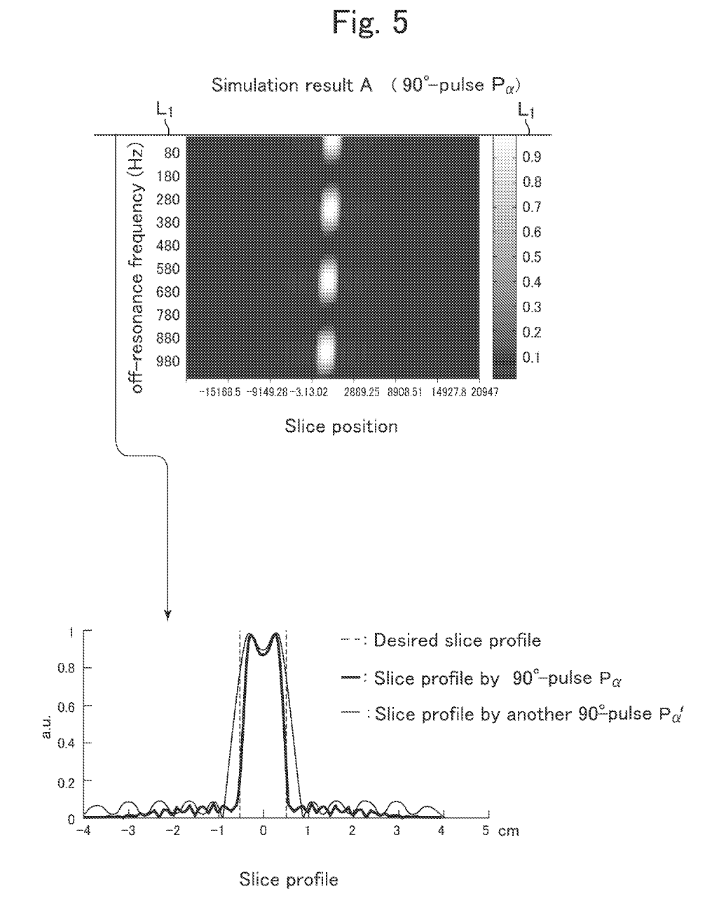

FIG. 5 shows the slice profile at the position (line L1-L1) of off-resonance frequency 0 Hz of the simulation result A.

The broken line in FIG. 5 represents a desired slice profile and the thick solid line represents the slice profile by the 90°-pulse Pα in this embodiment. In FIG. 5, the slice profile by another 90°-pulse Pα′ is also indicated by the thin solid line for the purpose of comparison. The simulation conditions with respect to another 90°-pulse Pα′ are as listed below:

Number of subpulses: 8
Spectral band width: 400 Hz
Spatial band width: 3461.5 Hz
Overall pulse length: 10.08 ms
Position of first null: 375 Hz
Minimum slice thickness: 3.63 mm

While another 90°-pulse Pα′ has the position of the first null at 375 Hz, the 90°-pulse Pα in this embodiment has the position of the first null at 150 Hz. Thus, the position of null of the 90°-pulse Pα is smaller than that of another 90°-pulse Pα′, so that the length of subpulses of the 90°-pulse Pα can be increased. Under the above-mentioned simulation conditions, the 90°-pulse Pα in this embodiment makes it possible to increase the length of each subpulse by 70% or so as compared with another 90°-pulse Pα′. Therefore, as shown in FIG. 5, use of the 90°-pulse Pα in this embodiment makes it possible to obtain a more favorable slice profile than with another 90°-pulse Pα′.

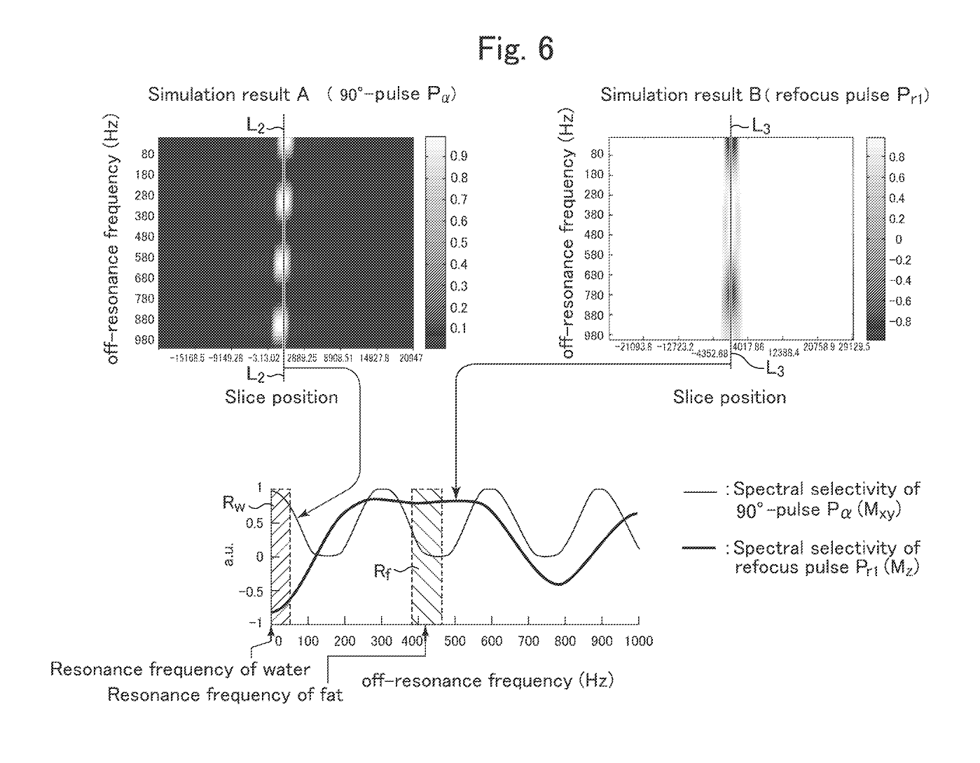

FIG. 6 shows the spectral selectivity in the center at the slice position of the simulation results A and B.

In a graph at the bottom side of the FIG. 6, a thin solid line and a thick solid line are shown. The thin solid line represents the spectral selectivity in the slice center L2-L2 of the simulation result A (the 90°-pulse Pα). The thick solid line represents the spectral selectivity in the slice center L3-L3 of the simulation result B (the refocus pulse Pᵣ₁).

First, description will be given to the spectral selectivity (thin solid line) of the 90°-pulse Pα.

As is apparent from the spectral selectivity of the 90°-pulse Pα (thin solid line), the transverse magnetization is Mxy≈0.8 to 1 in a frequency region R_{W} (the resonance frequency of water (off-resonance frequency 0 Hz) and the frequencies in proximity thereto). Meanwhile, the transverse magnetization is Mxy≈0 to 0.2 in a frequency region R_{f} (the resonance frequency of fat (off-resonance frequency 420 Hz) and the frequencies in proximity thereto).

Description will be given to the spectral selectivity (thick solid line) of refocus pulse Pᵣ₁.

At a frequency region R_{W}, a value of the longitudinal magnetization is approximately equal to −0.7 (Mz≈0.7) by the refocus pulse Pᵣ₁. Since the initial condition of the longitudinal magnetization is Mz=+1, the refocus pulse Pᵣ₁ can change the longitudinal magnetization of spin at the frequency region R_{W} from Mz=+1 (positive value) to Mz≈0.7 (negative value). That is, the refocus pulse Pᵣ₁ has such spectral selectivity that the polarity of the longitudinal magnetization at the frequency region R_{W} reverses. Therefore, the spin of water having Mxy≈1 by the 90°-pulse Pα is dephased with time; however, the refocus pulse Pᵣ₁ can refocus the phase of the spin of water to increase the intensity of water signals.

On the other hand, at a frequency region R_{f}, a value of the longitudinal magnetization is approximately equal to +0.8 (Mz≈+0.8) by the refocus pulse Pᵣ₁. Since the initial condition of the longitudinal magnetization is Mz=+1, even when the refocus pulse Pᵣ₁ is transmitted, the polarity of the longitudinal magnetization of spin can be kept positive (+) at the frequency region R_{f}. That is, the refocus pulse Pᵣ₁ has such spectral selectivity that the polarity of the longitudinal magnetization at the frequency region R_{f} dose not reverse. Therefore, the refocusing of the phase of spin by the refocus pulse Pᵣ₁ is suppressed at the frequency region R_{f}, so that fat signals can be sufficiently suppressed.

Therefore, the following is understood from the result of simulation shown in FIGS. 4 to 6: use of the pulse sequence PS1 (shown in FIG. 3) in this embodiment makes it possible to obtain an image with fat sufficiently suppressed even though the thickness of a slice is reduced.

In this embodiment, the 90°-pulse Pα used in the pulse sequence PS1 has such spectral selectivity that the transverse magnetization of fat is made smaller than the transverse magnetization of water. Therefore, the greater effect of suppressing fat can be obtained.

The pulse sequence PS1 can be applied to, for example, diffusion-weighted imaging using single spin echo or tensor imaging using single spin echo.

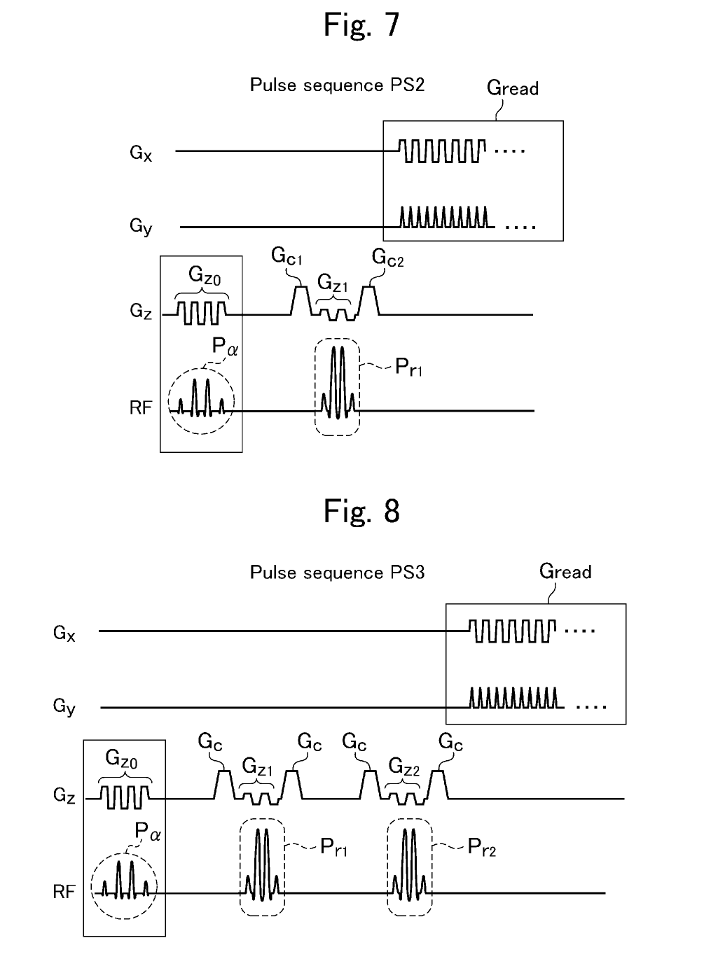

To reduce the influence of transverse magnetization Mxy due to the refocus pulse Pᵣ₁, a crusher gradient may be applied before and after the gradient field G_{z1}. FIG. 7 shows an example of a pulse sequence PS2 with the crusher gradient G_{c} applied before and after the gradient field G_{z1}.

The pulse sequences PS1 and PS2 shown in FIG. 3 and FIG. 7 have one refocus pulse. However, the number of refocus pulses is not limited to one and multiple refocus pulses may be provided.

FIG. 8 shows an example of a pulse sequence PS3 provided with multiple refocus pulses.

In the example in FIG. 8, an additional refocus pulse Pᵣ₂ is provided in addition to the refocus pulse Pᵣ₁. Provision of the additional refocus pulse Pᵣ₂ makes it possible to reduce the slice thickness. In the example in FIG. 8, the crusher gradient G_{c} is applied. However, the crusher gradient G_{c} may be removed as required. Further, in the example in FIG. 8, the readout gradient field G_{read} is provided after the additional refocus pulse Pᵣ₂. However, a further readout gradient field G_{read} may be provided between the refocus pulse Pᵣ₁ and the additional refocus pulse Pᵣ₂.

The pulse sequence PS3 shown in FIG. 8 can be applied to, for example, diffusion-weighted imaging using dual spin echo or tensor imaging using dual spin echo. The additional refocus pulse Pᵣ₂ can be used to reduce artifacts arising form eddy current. One of the refocus pulses Pᵣ₁ and Pᵣ₂ may be sinc pulse or SLR pulse. For example, refocus pulse Pᵣ₁ and/or refocus pulse Pᵣ₂ can be an SLR pulse as described in “Parameter relations for the Shinnar-Le Roux selective excitation pulse design algorithm,” by J. Pauly et al., IEEE Trans. Med. Imaging, Vol. 10, pp. 53-65 (1991).

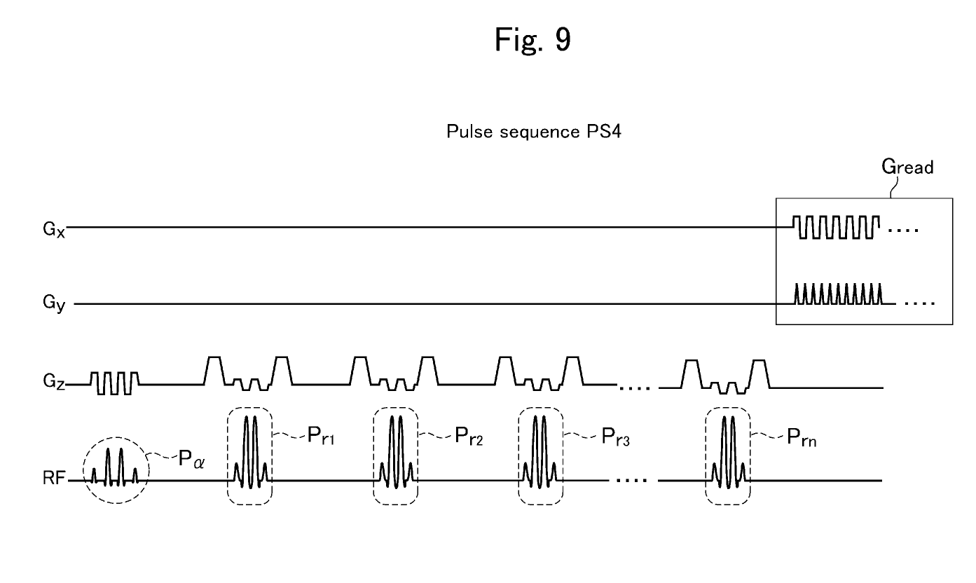

The pulse sequence PS3 shown in FIG. 8 is provided with two refocus pulses; however, n (n is three or more) refocus pulses Pᵣ₁-Pₘ, may be provided as in the pulse sequence PS4 shown in FIG. 9. In FIG. 9, m (<n) of n refocus pulses Pᵣ₁-Pₘ, may be sinc pulse or SLR pulse. Further, in the example in FIG. 9, the readout gradient field G_{read} is provided after the refocus pulse Pₘ. However, a further readout gradient field G_{read} may be provided between each refocus pulse.

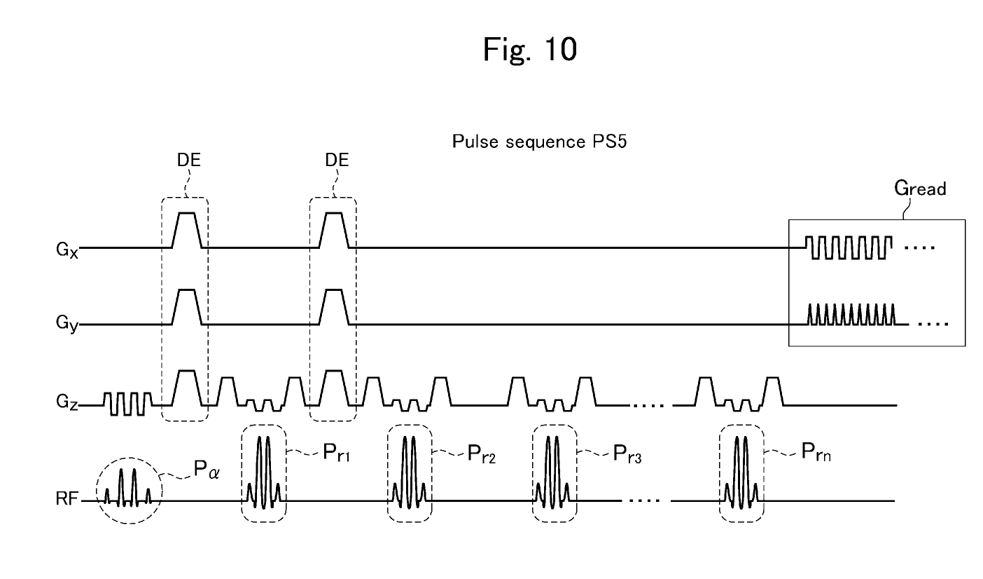

Further, as shown in the pulse sequence PS5 shown in FIG. 10, diffusion encodes DE for detecting the motion of water may be provided as required. Provision of the diffusion encodes DE makes it possible to do diffusion weighted imaging or diffusion tensor imaging. In the example in FIG. 10, the diffusion encodes DE with the same amplitude are provided on any of the three axes Gₓ, G_{y} and G_{z}. However, different diffusion encodes from FIG. 10 may be provided. For example, in diffusion weighted imaging, a diffusion encode may be provided on each axis alternately in order to quantify the amount of diffusion within each voxel. In diffusion tensor imaging, diffusion encodes with various amplitudes may be provided in all three axes to determine the diffusion tensor information within each voxel.

The above-mentioned pulse sequences PS1 to PS5 are also applicable to functional MRI.

The above-mentioned pulse sequences PS1 to PS5 are pulse sequences for the spin echo method. However, the invention may be applied to pulse sequences for the gradient echo method.

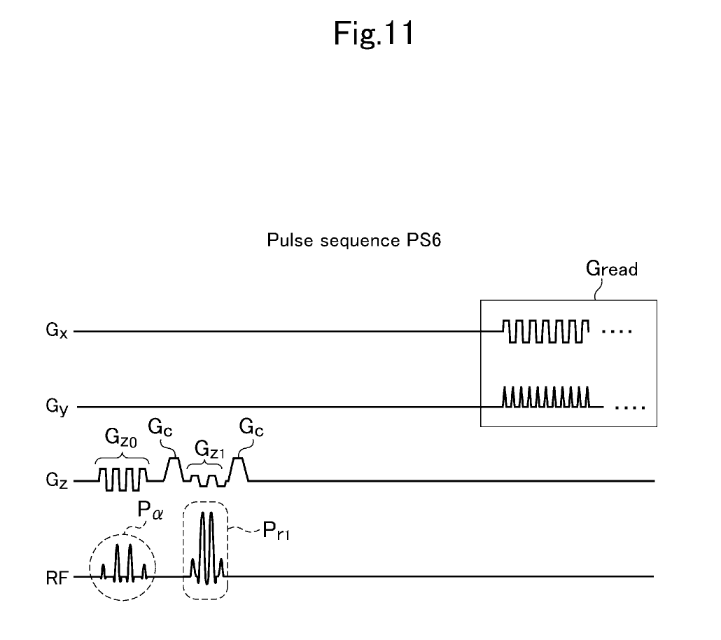

FIG. 11 shows an example that is applied to a pulse sequence for the gradient echo EPI.

The pulse sequence PS6 includes an α°-pulse Pα and a refocus pulse Pᵣ₁. The refocus pulse Pᵣ₁ is provided in a position adjacent to the α°-pulse Pα. As the result of providing the refocus pulse Pᵣ₁ as mentioned above, an image with fat sufficiently suppressed can be obtained even though the thickness of a slice is reduced.

While the invention has been particularly shown and described with references to preferred embodiments thereof, it will be understood by those skilled in the art that various changed in form and details may be made therein without departing from the scope of the invention. For example, in this embodiment, the α°-pulse Pα is 90° pulse, however, the α°-pulse Pα is not limited to 90° pulse. Further, in this embodiment, the refocus pulse Pᵣ₁ is 180° pulse, however, the refocus pulse Pᵣ₁ is not limited to 180° pulse as long as the refocusing of the phase of the spin of fat can be suppressed. And further, in this embodiment, the number of subpulses of each of the α°-pulse Pα and the refocus pulse Pᵣ₁ is 4, however, the number of subpulses can be changed as required.

In this embodiment, the example is described where water is enhanced and fat is suppressed. However, the invention can be applied to the case where water is suppressed or a substance (e.g. metabolite) different from fat and water is suppressed.

1. A magnetic resonance imaging apparatus that carries out a pulse sequence for making a signal of a first substance within an object smaller than a signal of a second substance within the object, the magnetic resonance imaging apparatus comprising a processing unit configured to apply the pulse sequence to the object,
wherein the pulse sequence comprises an α°-pulse for exciting the object, a refocus pulse for refocusing a phase of spin within a region excited by the α°-pulse, and a readout gradient field for acquiring a magnetic resonance signal from the region,
wherein the α°-pulse has a spectral selectivity such that a transverse magnetization of the first substance is made smaller than a transverse magnetization of the second substance, and
wherein the refocus pulse has a spectral selectivity such that a phase of spin of the second substance is refocused and refocusing of a phase of spin of the first substance is suppressed.

2. The magnetic resonance imaging apparatus according to claim 1,
wherein the pulse sequence is a pulse sequence for one of diffusion-weighted imaging using single spin echo and tensor imaging using single spin echo.

3. The magnetic resonance imaging apparatus according to claim 1,
wherein the pulse sequence comprises an additional refocus pulse having a spectral selectivity such that the phase of spin of the second substance is refocused and the refocusing of the phase of spin of the first substance is suppressed.

4. The magnetic resonance imaging apparatus according to claim 3,
wherein the pulse sequence comprises a further readout gradient field for acquiring the magnetic resonance signal from the region, the further readout gradient field provided between the refocus pulse and the additional refocus pulse.

5. The magnetic resonance imaging apparatus according to claim 3,
wherein the pulse sequence is a pulse sequence for one of diffusion-weighted imaging using dual spin echo and tensor imaging using dual spin echo.

6. The magnetic resonance imaging apparatus according to claim 1, wherein the pulse sequence comprises:
a gradient field applied while the refocus pulse is transmitted; and
a crusher pulse applied before and after the gradient field.

7. The magnetic resonance imaging apparatus according to claim 1,
wherein the pulse sequence comprises a diffusion encode for detecting a motion of the second substance at least one of an x-axis, a y-axis, and a z-axis.

8. The magnetic resonance imaging apparatus according to claim 1,
wherein the spectral selectivity of the α°-pulse is such that a position of null where the transverse magnetization of the first substance is most suppressed occurs between a resonance frequency of the first substance and a resonance frequency of the second substance.

9. The magnetic resonance imaging apparatus according to claim 1,
wherein the α°-pulse is a 90°-pulse.

10. The magnetic resonance imaging apparatus according to claim 1,
wherein the spectral selectivity of the refocus pulse is such that a polarity of a longitudinal magnetization at a position of a resonance frequency of the first substance does not reverse and a polarity of a longitudinal magnetization at a position of the resonance frequency of the second substance reverses.

11. The magnetic resonance imaging apparatus according to claim 1,
wherein a region where the spin is refocused by the refocus pulse is wider than the region excited by the α°-pulse.

12. The magnetic resonance imaging apparatus according to claim 1,
wherein the refocus pulse is a 180°-pulse.

13. The magnetic resonance imaging apparatus according to claim 1,
wherein the first substance is fat and the second substance is water.

14. The magnetic resonance imaging apparatus according to claim 1,
wherein the first substance is water and the second substance is fat.

15. A method for using a magnetic resonance imaging apparatus to carry out a pulse sequence for making a signal of a first substance within an object smaller than a signal of a second substance within the object, the method comprising:
transmitting an α°-pulse to excite the object, the α°-pulse having a spectral selectivity such that a transverse magnetization of the first substance is made smaller than a transverse magnetization of the second substance;
transmitting a refocus pulse to refocus a phase of spin within a region of the object excited by the α°-pulse, the refocus pulse having a spectral selectivity such that a phase of spin of the second substance is refocused and refocusing of a phase of spin of the first substance is suppressed; and
transmitting a readout gradient field to acquire a magnetic resonance signal from the region.

16. The method according to claim 15, further comprising:
transmitting an additional refocus pulse having a spectral selectivity such that the phase of spin of the second substance is refocused and the refocusing of the phase of spin of the first substance is suppressed.

17. The method according to claim 16, further comprising:
transmitting a further readout gradient field to acquire the magnetic resonance signal from the region, the further readout gradient field applied between the refocus pulse and the additional refocus pulse.

18. The method according to claim 15, further comprising:
transmitting a gradient field while the refocus pulse is transmitted; and
transmitting a crusher pulse before and after the gradient field.

19. The method according to claim 15, wherein transmitting an α°-pulse to excite the object further comprises transmitting an α°-pulse having a spectral selectivity such that a position of the null where the transverse magnetization of the first substance is most suppressed occurs between a resonance frequency of the first substance and a resonance frequency of the second substance.

20. The method according to claim 15, wherein transmitting a refocus pulse further comprises transmitting a refocus pulse having a spectral selectivity such that a polarity of a longitudinal magnetization at a position of a resonance frequency of the first substance does not reverse and a polarity of a longitudinal magnetization at a position of a resonance frequency of the second substance reverses.
